(19) United States
(12) Patent Application Publication
(10) Pub. No.: US 2019/0108095 A1
(43) Pub. Date: Apr. 11, 2019

(54) DATA INTEGRITY IN NON-VOLATILE STORAGE

(71) Applicant: Intel Corporation, Santa Clara, CA (US)

(72) Inventors: Yi ZOU, Portland, OR (US); Arun RAGHUNATH, Portland, OR (US); Anjaneya R. CHAGAM REDDY, Chandler, AZ (US); Sujoy SEN, Beaverton, OR (US); Tushar Sudhakar GOHAD, Phoenix, AZ (US)

(21) Appl. No.: 16/213,563

(22) Filed: Dec. 7, 2018

(51) Int. Cl. G06F 11/10; G11C 29/52

(52) U.S. Cl. CPC G06F 11/1068; G06F 11/1004; G11C 29/52

(57) ABSTRACT

To reduce the cost of ensuring the integrity of data stored in distributed data storage systems, a storage-side system provides data integrity services without the involvement of the host-side data storage system. Processes for storage-side data integrity include maintaining a block ownership map and performing data integrity checking and repair functions in storage target subsystems. The storage target subsystems are configured to efficiently manage data stored remotely using a storage fabric protocol such as NVMe-oF. The storage target subsystems can be implemented in a disaggregated storage computing system on behalf of a host-side distributed data storage system, such as software-defined storage (SDS) system.

### TECHNICAL FIELD

The technical field relates generally to computer data storage, and in particular to managing data integrity of data stored in non-volatile memory storage devices.

### BACKGROUND

Modern storage systems in today's data centers store data distributed over multiple storage devices. Although storage devices are equipped with built-in firmware and hardware logic to perform data integrity checking, data can still be corrupted by various processing errors, such as transmitting the data over noisy wires or buses.

Various industry solutions for providing end-to-end integrity checking have been proposed, such as extending the transmission protocols for transporting data to include a data integrity extension and data protection information (PI) field that conform to the T10 subcommittee proposal of the International Committee for Information Technology Standards. However, such solutions require hardware and protocol support that is expensive and impractical to use in the modern scale-out cloud environments supported in today's data centers.

For this reason, most large-scale distributed storage systems employ software-defined storage (SDS) solutions to manage the storage of data, including providing data integrity checks to ensure the integrity of data stored in the system. Data integrity checks typically include algorithms applied to the data such as a calculation of a checksum that can be used to detect errors in the data. Data integrity checks performed in SDS allow the distributed storage system to provide a high level of confidence in the expected data integrity even in the presence of noise on the input/output (I/O) path to the physical storage media. It also does not require expensive hardware or protocol complexity (as with the T10 PI and data integrity transmission protocol extension solutions). However, as a trade-off, SDS data integrity incurs additional costs in processor, memory, and network bandwidth, particularly when data is stored remotely since data is relayed back and forth between the SDS system and the storage media to check the integrity of stored data and repair corrupted data.

### BRIEF DESCRIPTION OF THE DRAWINGS

The described embodiments are illustrated by way of example and not limitation in the figures of the accompanying drawings. The methods, processes and logic depicted in the figures that follow can comprise hardware (e.g. circuitry, dedicated logic, controllers, etc.), software (such as is run on a general-purpose computer system or a dedicated machine, e.g. a software module or logic), and interfaces (such as a memory interface) between hardware and software, or a combination of both. Although the depicted methods, processes and logic may be described in terms of sequential operations, it should be appreciated that some of the described operations can be performed in a different order. Moreover, some operations can be performed in parallel rather than sequentially. The following figures include like references that indicate similar elements and in which:

FIG. 1 is a schematic block diagram of an example computer storage system in which data integrity in non-volatile storage can be implemented in accordance with various examples described herein;

FIG. 2 is a schematic block diagram of an example computer storage system in which data integrity in non-volatile storage can be implemented in accordance with various examples described herein;

FIG. 3 is a block diagram illustrating further details of an example computer storage system in which data integrity in non-volatile storage can be implemented in accordance with various examples described herein;

FIG. 4 is a block diagram illustrating further details of an example computer storage system in which data integrity in non-volatile storage can be implemented in accordance with various examples described herein;

FIG. 5 illustrates an example of a disaggregated storage computing system in which embodiments of processes for a data integrity service in non-volatile storage can be implemented, either in whole or in part, in accordance with various examples described herein; and

FIG. 6 illustrates an example of a computer system in which embodiments of processes for a data integrity service in non-volatile storage can be implemented, either in whole or in part, in accordance with various examples described herein.

Other features of the described embodiments will be apparent from the accompanying drawings and from the detailed description that follows.

### DESCRIPTION OF THE EMBODIMENTS

In modern software-defined storage (SDS) solutions such as Red Hat Ceph, OpenStack Swift, Alibaba, Pangu and Apache Hadoop, etc., data storage is managed through software independently of the storage hardware that stores the data. One of the services that are typically provided by SDS is a software “scrubbing” service to perform data integrity checking, such as “scrubber” in Ceph or “auditor” in Swift. For example, for a given piece of data being “scrubbed,” all versions of the data, including redundant versions of data referred to as replicas, or erasure coded (EC) portions of data that can be combined to produce the data if using erasure coding to improve fault tolerance, are retrieved from the physical media where they are stored and compared or otherwise analyzed for integrity using an algorithm, such as a majority vote algorithm. Based on the results of the algorithm an SDS determines whether the data has been corrupted and, if needed, repairs the data, including storing another uncorrupted copy of the data.

In a large data center environment, data, including redundant versions of data, is typically stored using distributed data storage. Distributed data storage generally refers to storing data in different locations, including in separate physical media accessible through a storage server. The storage server is typically organized into one or more storage nodes or clusters of multiple storage servers. Retrieving the data, and all of the redundant versions of the data, to enable an SDS system to perform the “scrubbing” service can incur significant data transfer and processing costs, especially when data is stored using distributed data storage.

For example, the data transfer and processing costs can be multiplied when the data being “scrubbed” is stored in distributed data storage based on a typical 3-way replication scheme where there are three replicas of the data stored in different locations and/or separate physical media accessible through one or more storage nodes. For data that is stored remotely in distributed data storage, the data transfer costs can be especially significant. Moreover, with larger and larger capacity storage drives, the processing costs for ensuring the integrity of data places a large burden on the storage nodes of the distributed data storage architecture.

To address the overhead associated with providing data integrity services for stored data, embodiments of data integrity for non-volatile storage as herein described ensures the integrity of stored data with little or no involvement from the data storage systems that generate the data, such as an SDS system. As such, embodiments of data integrity for non-volatile storage greatly reduce overhead in bandwidth and latency caused by existing data integrity solutions.

In one embodiment, a framework for a preventive self-scrubbing mechanism is provided for data storage systems that generate data stored remotely using a storage fabric. A storage fabric generally refers to a storage network architecture that integrates management and access to data that is stored remotely. In one embodiment, data stored remotely using a storage fabric includes data stored remotely in non-volatile storage separately from the data storage systems that generate data, such as an SDS system.

In one embodiment, the framework for a preventive self-scrubbing mechanism leverages the capabilities of distributed data storage using a disaggregated architecture. Disaggregated architecture refers to disaggregated resources (e.g., memory devices, data storage devices, accelerator devices, general purpose processors) that are selectively allocated, deallocated and logically coupled to form a composed node. The composed node can function as, for example, a storage server.

Disaggregated architecture improves the operation and resource usage of a data center relative to data centers that use conventional storage servers containing compute, memory and storage in a single chassis. In one embodiment, data integrity for non-volatile storage can be provided completely within a disaggregated architecture, such as the Rack Scale Design (RSD) architecture provided by Intel Corporation.

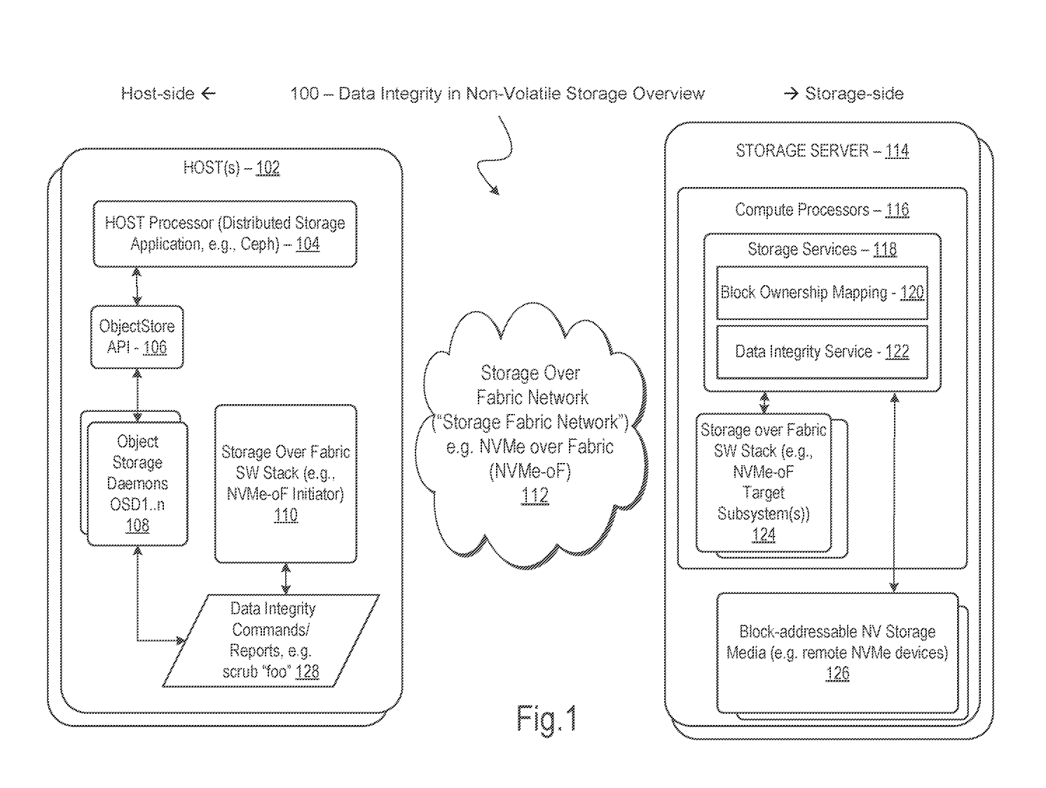

FIG. 1 is a schematic block diagram overview 100 illustrating how components for providing data integrity in non-volatile storage can be implemented in accordance with various examples described herein. Referring to FIG. 1, by way of example only and not limitation, one or more host systems 102 includes a host processor 104 of a distributed storage application, such as an SDS system (e.g., Ceph). The host 104 typically stores data using an object store application programming interface (API) 106 to generate object storage daemons (OSD) 1 through n (OSD1, . . . n 108). Each OSD 108 is capable of transmitting commands and data 128 to the corresponding storage subsystem(s) 124 of a storage server 114.

The commands and data 128 are transported over a network configured with a storage-over-fabric network protocol, generally referred to herein as a storage fabric network 112. In one embodiment, the storage-over-fabric network protocol can be the non-volatile memory express over fabric protocol (NVMe-oF).

By way of example only and not limitation, the transport layer of the storage fabric network 112 is provided using an Ethernet fabric between the host(s) 102 and the storage server(s) 114 configured with a remote direct memory access (RDMA) transport protocol. NVMe-oF and the RDMA transport protocols enable the host(s) 102 to efficiently relay commands and data directly to the non-volatile memory express (NVMe) devices. NVMe devices are capable of communicating directly with a system processor providing high-speed access to data in accordance with the NVMe interface specification. The NVMe-oF network protocol used in storage fabric network 112 extends the benefits of NVMe devices to a remote host, such as host(s) 102. Other types of network and transport protocols could be used, such as a Fibre Channel Protocol or other protocols that support block storage data transport to and from non-volatile storage devices.

In one embodiment, in the context of an SDS system, the commands and data can be relayed to and from an OSD 108 over the storage fabric network 112 via an NVMe-oF initiator 110 configured on the SDS system's host-side of the storage fabric, and a corresponding one or more NVMe-oF target subsystems 124 configured on an opposite side of the storage fabric network 112, i.e., the storage-side.

In one embodiment, the corresponding one or more NVMe-oF target subsystems 124 can be implemented in compute processors 116 of a storage server 114. In one embodiment, the storage server 114 can be efficiently implemented as a composed node of a data storage system provided using a disaggregated architecture. The composed node is formed from disaggregated resources, including compute processors 116 and storage media 126. In one embodiment, the compute processors 116 and storage media 126 reside in one or more storage racks on the storage-side of the storage fabric network 112. The storage racks provide the underlying data storage hardware in a data center using a disaggregated architecture.

For example, in one embodiment, the disaggregated resources include compute modules and NVMe drives (also referred to herein as NVMe devices) housed in a storage rack. The compute modules and NVMe devices are composed to form the storage server 114. By way of example only and not limitation, the compute modules function as the compute processors 116 for implementing the NVMe-oF target subsystems 124 for controlling the storage of data. The NVMe devices function as the pool of block-addressable NV storage media 126 for storing data. Taken together, the NVMe-oF target subsystems 124 and block-addressable NV storage media 126 form the composed node(s) that function as the storage server(s) 114. In one embodiment, NVMe-oF target subsystems 124 control access to the block-addressable NV storage media 126 to provide remote storage capacity for the data storage needs of a distributed storage application 104 operating on host 102, such as an SDS system.

In one embodiment, storage over fabric software (SW) stacks configure and establish a logical connection between the NVMe-oF initiator 110 on the host-side, and the corresponding NVMe-oF target subsystem(s) 124 on the storage-side. Once the logical connection is established, the target subsystem(s) 124 exposes to each of the OSDs 108, via the NVME-oF initiator 110, available blocks of storage capacity on the block-addressable NV storage media 126. The available blocks of storage capacity are those blocks that are accessible to the respective target subsystem(s) 124.

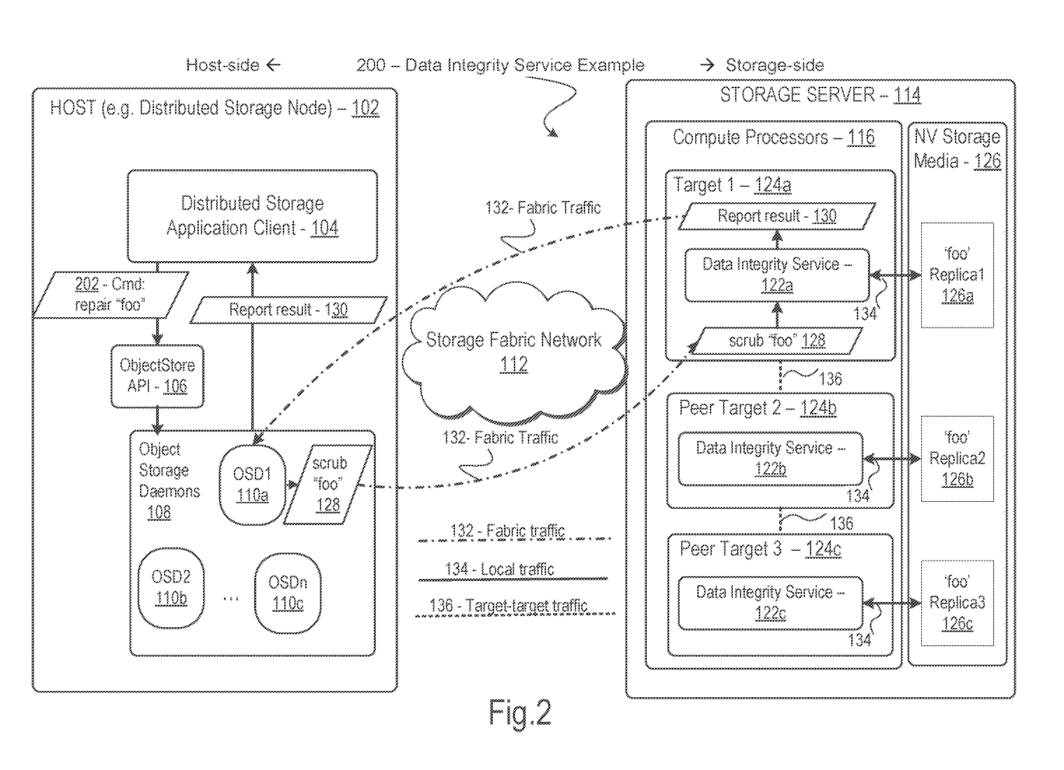

In one embodiment, a pool of block-addressable NV storage media 126, such as a set of NVMe devices in a given storage server 114, is accessed via a Peripheral Component Interconnect Express (PCIe) bus (not shown). An NVMe device 126 is an NVM device configured for access using NVM Express, a controller interface that facilitates accessing NVM devices through the PCIe bus. Each of the corresponding target subsystem(s) 124 manage the data stored on the NVMe devices 126 on behalf of the host(s) 102, including providing various storage services 118 for managing data stored on the NVMe devices 126. The storage services 118 pertinent to embodiments of data integrity for non-volatile storage as described herein include block ownership mapping 120 and the data integrity service 122 as will be described in further detail with reference to FIGS. 2-4.

With reference to FIG. 2, a data integrity service example 200 is illustrated in which the integrity of data represented as a storage object ‘foo’ is determined in accordance with embodiments of data integrity in non-volatile storage as herein described. As shown, the data, represented here as the storage object ‘foo,’ is stored in NVMe device(s) 126 based on a 3-way replication scheme of the distributed storage system operating on host 102. For example, the object ‘foo’ is stored in redundant versions ‘foo’ Replica1 126a, ‘foo’ Replica2 126b and ‘foo’ Replica3 126c. In the description that follows, the data integrity service example 200 refers to redundant versions of data/objects. However, it should be understood that the integrity of data can be determined for other types of data/objects as well, including erasure coded data/objects for data protection, alternatively or in addition to replicated data/objects.

In one embodiment, each redundant version of the object is associated with a target subsystem 124, such as Target1 124a, and one or more peers of Target1, such as Peer Target2 124b and Peer Target3 124c. Each target subsystem 124, including each peer target subsystem, is capable of providing a data integrity service 122, respectively 122a, 122b, 122c, Rather than retrieving data from the block-addressable NVMe device(s) 126 and sending that data back to the OSD 108 on the host-side of the storage fabric for data integrity services, each target subsystem 124a, 124b and 124c performs a local data integrity check and repair operation on the data (or the redundant versions of the data) under the respective target subsystem's control.

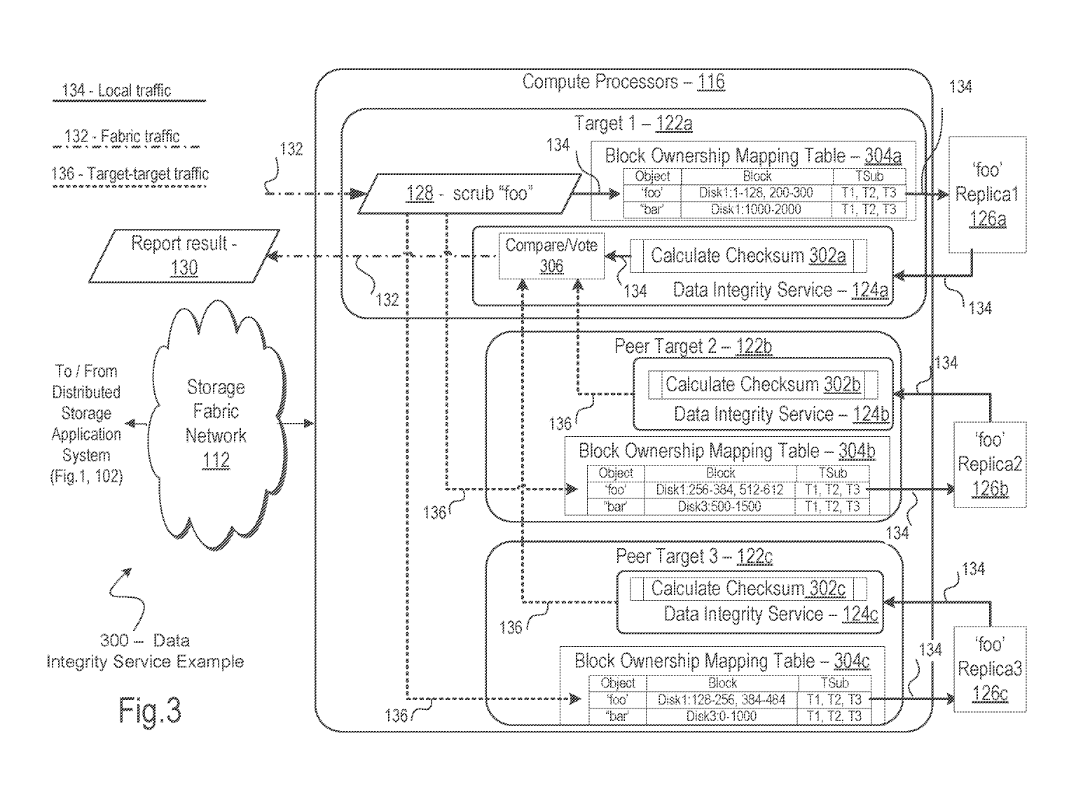

In one embodiment, the association between the data stored as objects and the target subsystems that manage them is based on the block ownership mapping 120 and other storage services 118 provided in the storage server 114 (as will be described in further detail with reference to FIG. 3).

With reference to the illustrated example in FIG. 2, in one embodiment of data integrity for non-volatile storage, a host-operated distributed storage application client 104 is capable of issuing a command 202 to repair an object, such as the example command “Cmd repair ‘foo,’” requesting that integrity of the data identified with object identifier ‘foo’ be checked and repaired if needed. For example, on the host-side of the storage fabric network 112, an ObjectStore application programming interface (API) 106 receives the command 202 and interfaces with an object storage daemon 108 that functions as the NVMe-oF initiator 110 through configuration with the NVMe-oF SW stack, here referenced as OSD1 110a. The OSD1 110a in turn issues the data integrity command 128, e.g., “scrub ‘foo’” causing the data integrity command 128 to be sent directly to the target subsystem 124 with which OSD1 110a has been logically connected.

In a typical embodiment the data integrity command 128 is sent only once from the OSD 108 that received the original Cmd repair “foo” 202 from the distributed storage application client 104 via the ObjectStore API 106. In one embodiment, on the storage-side, at least one of the target subsystems can be discovered as having a logical connection with the sending OSD1 110a, e.g. Target1 124a. In turn, the discovered target, e.g., Target1 124a, receives the command “scrub ‘foo’” 128 and locally performs the data integrity service 122a as will be described in further detail with reference to FIG. 3.

In one embodiment, instead of performing the data integrity service in response to receiving the command “scrub ‘foo’” 128 from the host-side, any of the target subsystems 124, such as Target 1 124a, or the Peer Target2 124b and Peer Target3 124c, can initiate the performance of a data integrity service 122 for an object ‘foo’ stored on behalf of a host-operated SDS system automatically. For example, the data integrity service 122 can be performed either periodically or on-demand in response to a storage-side event, without the involvement of the host 102 operating the SDS system and/or other distributed storage application. Either way, upon completing the performance of the data integrity service 122 for the object ‘foo’, a target subsystem 124, such as Target 1 124a, notifies the OSD 108 associated with the data about the result of the data integrity service by sending a “report result” message back to the OSD 108 via the storage fabric network 112.

Whichever way the data integrity service 122 for the object ‘foo’ is initiated, whether in response to a host-side request or in response to a storage-side event, any of the target subsystems 124 that manage a replica of ‘foo’ are capable of receiving the data integrity command 128 to initiate the data integrity service 122, either directly over the storage fabric network 112 to a receiving target subsystem, such as Target1 124, or through a notification relayed from the receiving target subsystem to other peer target subsystems, such as Peer Target2 124b and Peer Target3 124c as will be described in further detail with reference to FIG. 3.

As noted above, regardless of how many redundant versions of the data might be stored remotely on the NVMe device(s) 126, the data integrity command 128 is sent only once from the OSD 108 to perform a data integrity service 122 on all versions of the data stored remotely on the NVMe device(s) 126. Likewise, whatever storage-side event might trigger execution of a data integrity command 128 need occur only once as well. All other communication and processes necessary to carry out the data integrity service 122 can be performed using an interface for a target-target communication path 136 and local communication 134 without adding to the fabric traffic 132 except, if needed, for sending back to the host-side OSD 108 associated with the storage-side target subsystem(s) 124 the result of performing the data integrity service 122.

In one embodiment the target-target communication path 136 can occur completely within a single storage server 114 but could also occur between target subsystems 124 and peers of the target subsystems 124 that are logically connected but reside in different storage servers 114. Either way managing the integrity of the stored data via the target-target communication path 136 minimizes the amount of data traffic that would otherwise occur over the storage fabric network 112.

In one embodiment, the amount of data traffic that occurs over the storage fabric network 112 can be further minimized or even eliminated when the data integrity service 122 is triggered by a storage-side event, thereby occurring automatically and without any involvement of the host-side data storage application upon whose behalf the data integrity services 122 have been performed. For example, a storage-side event could be configured to occur periodically or on demand to trigger operation of the data integrity service 122.

In one embodiment, the target-target communication path 136 can be local within a storage server 114 and/or a data center in which one or more storage servers 114 are deployed. In one embodiment, the target-target communication path 136 can be remote. For example, for implementing the proper failure domain of replicated data, each of the ‘foo’ replicas, ‘foo’ Replica1, 126a, ‘foo’ Replica2, 126b and ‘foo’ Replica3, 126c, would be stored in non-volatile storage media that typically reside in different power failure domains, i.e., storage media that are controlled in different storage servers 114 for the respective target subsystems 124. Even with increased target-target traffic between target subsystems 124 that are located in different power failure domains, managing the integrity of the stored data via the target-target communication path 136 minimizes the amount of data traffic that would otherwise occur over the storage fabric network 112.

In one embodiment, the communication interface between the target subsystems 124, like that of the storage fabric network 112, can be implemented using an NVMe-oF protocol, and the underlying transport can depend on the target subsystem vendor's choice, e.g. Ethernet or Infiniband with Remote Direct Memory Access (RDMA) transport layer, or the Fibre Channel Protocol.

FIG. 3 illustrates further details in data integrity service example 300 of data integrity for non-volatile storage implemented in accordance with various examples described herein. As noted earlier, one of the storage services 118 pertinent to data integrity for non-volatile storage is the block ownership mapping service 120 introduced in FIG. 1. In one embodiment, the block ownership mapping service 120 is implemented with a block ownership mapping table 304a/304b/304c that maps an identifier of the data, such as the object unique ID to the data blocks where the object is stored, e.g. Disk1:1-128, 200-300 for ‘foo’ Replica1 in Target 1 122a, where the Disk1:1-128, 200-300 refers to a location address in one of the NVMe devices comprising the NV storage media 126 where ‘foo’ Replica1 126 is currently stored. In one embodiment the block ownership mapping table 304a/304b/304c further identifies each of the target subsystems 124 responsible for managing the integrity of the data. For example, in one embodiment, all target subsystem(s) (Tsub) that manage a replica of ‘foo’, e.g. Target 1, Target 2 and Target 3, are identified as peers in the block ownership mapping table 304a/304b/304c, indicating that each of the target subsystem(s) is responsible for managing the data or redundant versions of the data.

As the data is moved and updated, the block ownership mapping table 304a/304b/304c is updated. In one embodiment, the block ownership mapping table 304a/304b/304c can be centralized for target subsystem(s) 124 that are part of the same storage server 114. In one embodiment, the block ownership mapping service 120 can be implemented as a database, or in other types of memory structures that facilitate organization and retrieval of the block ownership information.

In one embodiment, to carry out a comprehensive data integrity service 124, the target that receives the data integrity command 128 is responsible not only for performing a local data integrity service on the data that it manages, but also is responsible for initiating local data integrity services for data managed by peer target subsystems over the target-target communication path 132 established between the target subsystems 124.

For example, as illustrated in FIG. 3, the scrub ‘foo’ 128 command received in Target 1 122a can be broadcasted and/or unicasted as a notification to also scrub ‘foo’ to Peer Target 2 122b and Peer Target 3 122c over the target-target communication path 136. The receiving peer target then performs the data integrity service locally as the respective data integrity service 124b/124c illustrated in FIG. 3. Each peer target retrieves its own stored redundant version of the data being scrubbed, in this case, ‘foo’ Replica2 126b and ‘foo’ Replica3 126c and reports the result of the scrubbing the redundant version(s) of the data back to Target 1 122a from whom the notification was received. In turn, Target 1 122a collects the results from the peer targets and completes the data integrity service 124a on all of the redundant versions of the data, by performing a compare and vote algorithm, or other type of algorithm, that determines the integrity of the data, including which redundant version(s) of the data may or may not be corrupted.

In one embodiment, the data integrity services 124a/124b/124c performed in each of the respective target subsystems includes logic to calculate a checksum 302a/302b/302c to aid in determining the integrity of each redundant version of the data that is retrieved from the NVMe device(s) 126. The checksum is a value that represents the retrieved data and can be used as an indicator of an integrity of the data as compared to a checksum of another version of the data retrieved from the NVMe device(s) 126.

In one embodiment, if the request to repair ‘foo’ was initiated on the host-side, the receiving target subsystem, Target 1 122a reports the result of the comprehensive data integrity service in a report result message 130 transmitted over the fabric traffic path 132 back to the originating host-side OSD, e.g. OSD1 110a of the object storage daemons 108 generated by the distributed storage application client 104.

As can be seen from the above-described scenario, the request to repair ‘foo’ that would have otherwise resulted in actual I/O commands being issued from each object storage daemon (OSD1, OSD2, and OSD3 in this example) to retrieve the data blocks of the redundant versions of the object ‘foo’ from the NVMe fabric-side, is instead performed completely within the NVMe fabric-side. As a result, no data is transferred over the storage fabric network 112 to perform the data integrity service. More importantly, there is no involvement from the OSD1 110a (other than relaying the scrub ‘foo’ command if requested) and no involvement at all from the other object storage daemons, OSD2 110b or OSD3 110c. For a replication scheme with replication factor r, embodiments of data integrity for non-volatile storage as described herein can achieve an (r−1) times reduction on storage cluster network operated on the host-side and r times reduction on the fabric-side of the storage network. The trade-off is the (r−1) times increase in traffic on the target-target communication path 136. However, even with this increase in traffic on the target-target communication path 136, the total bandwidth reduction achieved on the storage fabric network 112 remains approximately a magnitude of a factor of r.

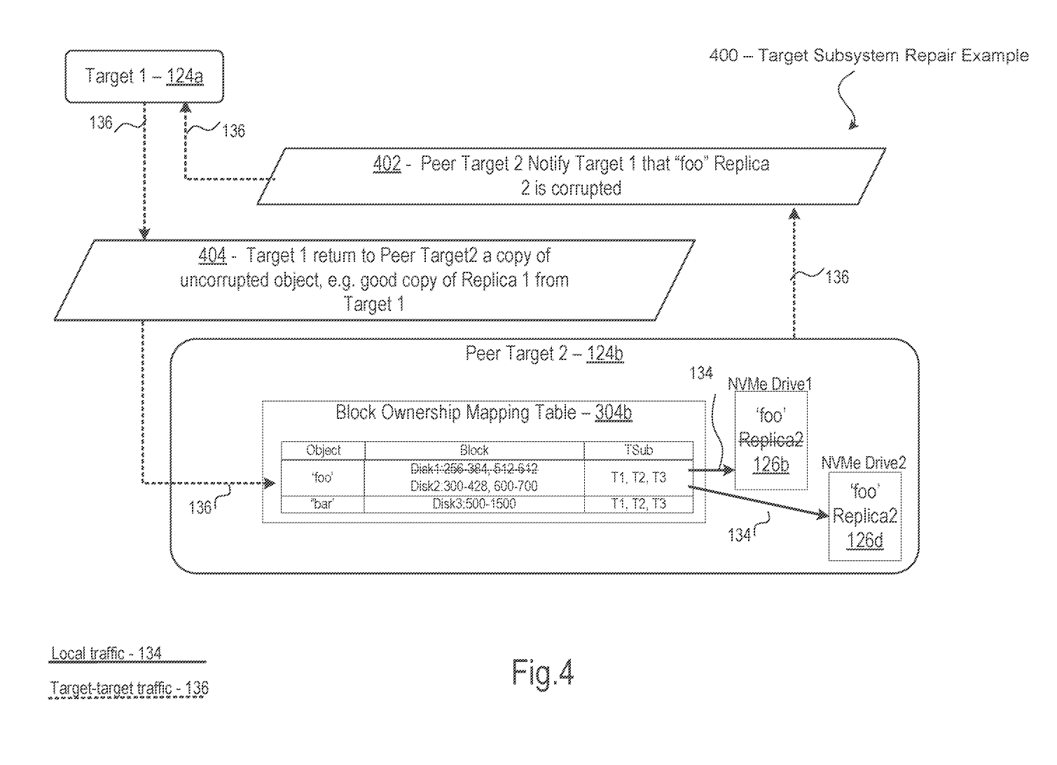

FIG. 4 illustrates further details of the data integrity service example in FIG. 3, particularly a repair example 400, in which a redundant version of the data is found to be corrupted and in need of repair. In one embodiment, once the receiving target subsystem 124a determines from any of the result of the data integrity service 122b reported by Peer Target 2 124b, or from the comprehensive data integrity service 122a performed by Target 1 124a that the redundant version ‘foo’ Replica2 126b has been corrupted, then Target 1 124a initiates a repair operation by returning to Peer Target 2 a copy of an uncorrupted object, e.g., a good copy of Replica1. Peer Target 2 124b can use the copy to repair, via local traffic paths 134 between the target and the NV storage media 126, the corrupted version stored on NVMe Drive1 with the good copy on NVMe Drive2 as uncorrupted ‘foo’ Replica2 126d.

As shown in FIG. 4, Peer Target 2 124b updates the block ownership mapping table 304 with the block locations of the good copy on NVMe Drive2, e.g. Disk2:300-428, 600-700, while marking for deletion the old block locations of the corrupted copy on NVMe Drive1, e.g. Disk 1:256-384, 512-612. The entire repair operation is performed amongst target subsystems 124 such that no data blocks of each replica ‘foo’ are retrieved and sent outside any individual target subsystem 124 of storage server 114 other than sending a correct version of the object ‘foo,’ i.e. a good copy, from one target subsystem to another target subsystem 124 whose current copy is corrupt.

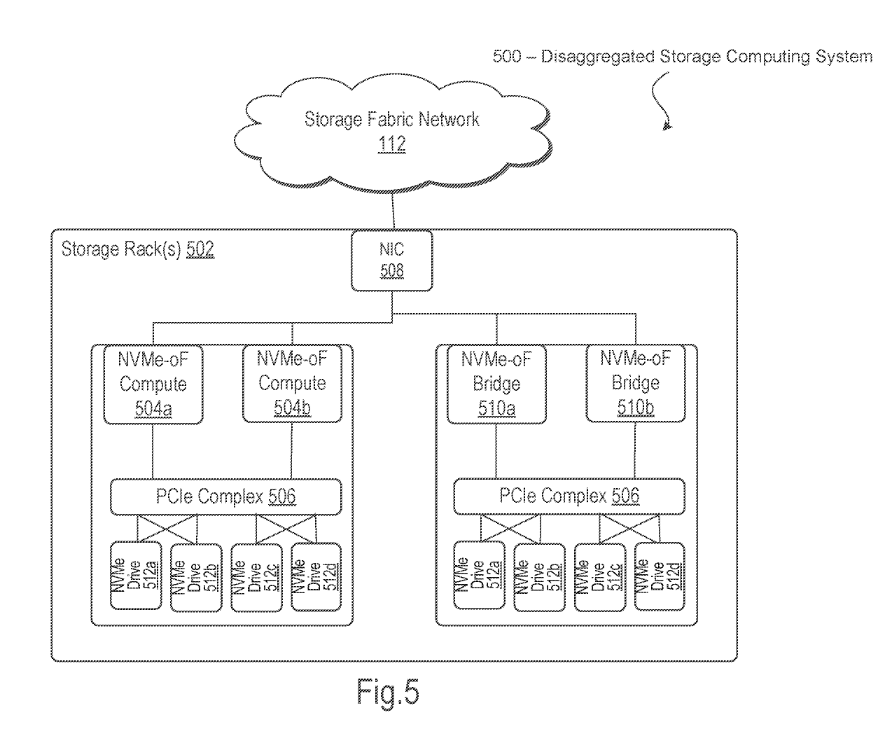

FIG. 5 illustrates an example of a disaggregated storage computing system 500 in which embodiments of processes for a data integrity service in non-volatile storage can be implemented, either in whole or in part, in accordance with various examples described herein. A storage fabric network 112 couples to a network interface card (NIC) 508 in a storage rack 502 in which disaggregated resources may cooperatively execute one or more workloads (e.g., applications on behalf of customers). In one embodiment the storage rack(s) 502 can be arranged in one or more rows into a pod (not shown) deployed in a data center. A typical data center can include a single pod or multiple pods.

In one embodiment, each storage rack 502 houses multiple sleds (not shown), each of which may be primarily equipped with a particular type of resource (e.g., memory devices, data storage devices, accelerator devices, general purpose processors), i.e., resources that can be logically coupled to form a composed node. In some embodiments, the resources in the sleds may be connected with a fabric using Intel Omni-Path technology. In other embodiments, the resources in the sleds may be connected with other fabrics, such as InfiniBand or Ethernet.

As described in more detail herein, resources within sleds may be allocated to a group (referred to herein as a “managed node”) containing resources from one or more sleds to be collectively utilized in the execution of a workload. The workload can execute as if the resources belonging to the managed node were located on the same sled. In a disaggregated architecture, the resources in a managed node may belong to sleds belonging to different racks, and even to different pods. As such, some resources of a single sled may be allocated to one managed node while other resources of the same sled are allocated to a different managed node (e.g., one processor assigned to one managed node and another processor of the same sled assigned to a different managed node).

In one embodiment, a storage server 114 can be implemented as a managed node containing resources from the sleds such as multiple NVMe-oF compute modules 504a/504b that function as the compute processors 116 and target subsystem(s) 124 for implementing in software the logic for the storage services 118. The workloads executed by the managed node include performing the storage services 118, including block ownership mapping 120 and data integrity service 122, in the target subsystem(s) 124 of a storage server 114.

In one embodiment the storage server 114 can be implemented as a managed node containing NVMe-oF bridge modules 510, 512. The NVMe-oF bridge modules 510a/510b can form a hardware-based target subsystem 124 in which the logic for managing data integrity for non-volatile storage is carried out at least in part inside an FPGA or application specific integrated circuit (ASIC). Either way, the NVMe-oF compute modules 504a/504b and NVMe-oF bridge modules 510a1510b are configured to connect to the NIC 508 to connect with the storage fabric network 112 as well as configured to connect to a PCIe-Complex 506 that connects to the NVMe drives 512a/512b/512c/512d. The NVMe drives 512a/512b/512c/512d are the physical media that comprise the NV storage media 126 in storage server 114.

In view of the foregoing, embodiments of data integrity for non-volatile storage described herein can be performed without consuming storage fabric network 112 bandwidth. Data integrity checking for non-volatile storage can also unburden the distributed storage application's 104 processor and networking resources (e.g. the object storage daemons 108/110a/110b/110c), which can be helpful for cloud service providers. The storage side of the storage fabric network 112 can proactively ensure integrity for data stored remotely in NV storage media 126 by performing data integrity services locally in each of the storage target subsystems 124. As such, scrubbing can be deployed as a preventive mechanism that mitigates a known issue of a host-side distributed storage application 104 experiencing a long tail latency due to remote storage media, e.g. NV storage media 126, being accessed by I/O during data scrubbing. As a result, embodiments of data integrity for non-volatile storage can reduce the total cost of data integrity services, especially when implemented in a data center using an efficient disaggregated storage computing system 500.

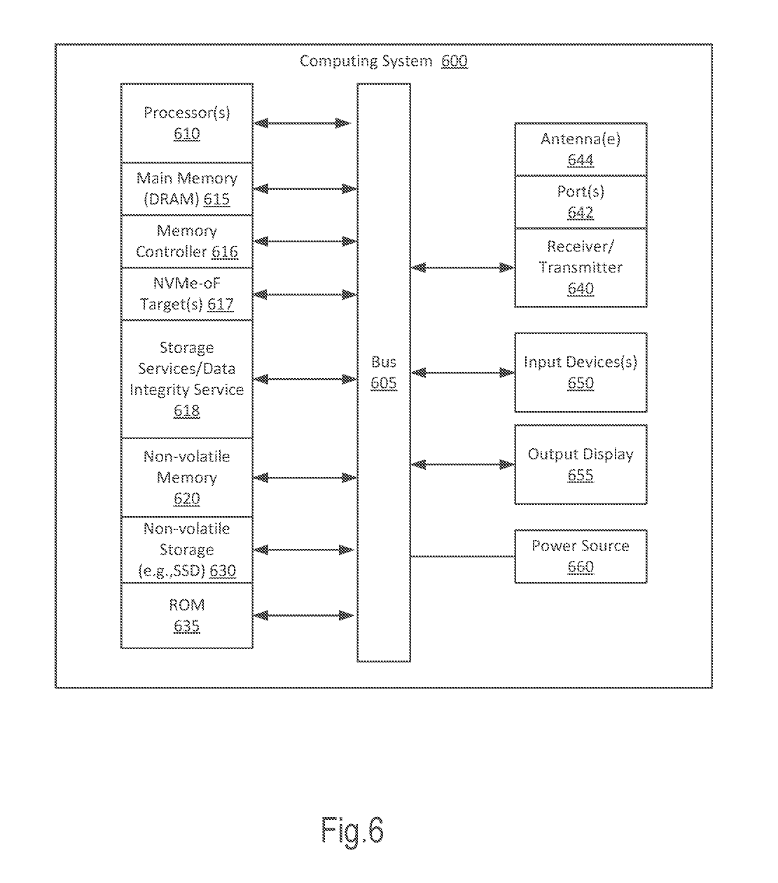

FIG. 6 is an illustration of a general computing system 600 in which data integrity for non-volatile storage can be implemented, including, for example, the logic for the NVMe-oF target subsystems 124 and related storage services 118, in accordance with an embodiment. In this illustration, certain standard and well-known components that are not germane to the present description are not shown. Elements that are shown as separate elements may be combined, including, for example, a SoC (System on Chip) combining multiple elements on a single chip.

In some embodiments, a computing system 600 may include a processing means such as one or more processors 610 coupled to one or more buses or interconnects, shown in general as bus 605. The processors 610 may comprise one or more physical processors and one or more logical processors. In some embodiments, the processors may include one or more general-purpose processors or special-purpose processors.

The bus 605 is a communication means for transmission of data. The bus 605 is illustrated as a single bus for simplicity but may represent multiple different interconnects or buses and the component connections to such interconnects or buses may vary. The bus 605 shown in FIG. 6 is an abstraction that represents any one or more separate physical buses, point-to-point connections, or both connected by appropriate bridges, adapters, or controllers.

In some embodiments, the computing system 600 further comprises a random access memory (RAM) or other dynamic storage device or element as a main memory 615 and memory controller 616 for storing information and instructions to be executed by the processors 610. Main memory 615 may include, but is not limited to, dynamic random access memory (DRAM). In some embodiments, the RAM or other dynamic storage device or element includes a modified data tracker logic 617 implementing data integrity for non-volatile storage.

The computing system 600 also may comprise a non-volatile memory 620; a storage device such as a solid-state drive (SSD) 630; and a read-only memory (ROM) 635 or another type of static storage device for storing static information and instructions for the processors 610. The term “non-volatile memory” or “non-volatile storage” as used herein is intended to encompass all non-volatile storage media, such as solid state drives (SSD) and other forms of non-volatile storage and memory devices, collectively referred to herein as a non-volatile memory (NVM) device.

An NVM device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also include a byte-addressable write-in-place three dimensional crosspoint memory device, or other byte addressable write-in-place NVM devices (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto-resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor-based memory device, or a combination of any of the above, or other memory. The memory device may refer to the die itself and/or to a packaged memory product.

In some embodiments, the computing system 600 includes one or more transmitters or receivers 640 coupled to the bus 605. In some embodiments, the computing system 600 may include one or more antennae 644, such as dipole or monopole antennae, for the transmission and reception of data via wireless communication using a wireless transmitter, receiver, or both, and one or more ports 642 for the transmission and reception of data via wired communications. Wireless communication includes, but is not limited to, Wi-Fi, Bluetooth™, near field communication, and other wireless communication standards.

In some embodiments, computing system 600 includes one or more input devices 650 for the input of data, including hard and soft buttons, a joystick, a mouse or other pointing device, a keyboard, voice command system, or gesture recognition system.

In some embodiments, computing system 600 includes an output display 655, where the output display 655 may include a liquid crystal display (LCD) or any other display technology, for displaying information or content to a user. In some environments, the output display 655 may include a touch-screen that is also utilized as at least a part of an input device 650. Output display 655 may further include audio output, including one or more speakers, audio output jacks, or other audio, and other output to the user.

The computing system 600 may also comprise a battery or other power source 660, which may include a solar cell, a fuel cell, a charged capacitor, near-field inductive coupling, or other system or device for providing or generating power in the computing system 600. The power provided by the power source 660 may be distributed as required to elements of the computing system 600.

It will be apparent from this description that aspects of the described embodiments could be implemented, at least in part, in software. That is, the techniques and methods described herein could be carried out in a data processing system in response to its processor executing a sequence of instructions contained in a tangible, non-transitory memory such as the memory 615 or the non-volatile memory 620 or a combination of such memories, and each of these memories is a form of a machine-readable, tangible storage medium.

Hardwired circuitry could be used in combination with software instructions to implement the various embodiments. For example, aspects of the described embodiments can be implemented as software installed and stored in a persistent storage device, which can be loaded and executed in a memory by a processor (not shown) to carry out the processes or operations described throughout this application. Alternatively, the described embodiments can be implemented at least in part as executable code programmed or embedded into dedicated hardware such as an integrated circuit (e.g., an application specific IC or ASIC), a digital signal processor (DSP), a field programmable gate array (FPGA), or controller which can be accessed via a corresponding driver and/or operating system from an application. Furthermore, the described embodiments can be implemented at least in part as specific hardware logic in a processor or processor core as part of an instruction set accessible by a software component via one or more specific instructions.

Thus the techniques are not limited to any specific combination of hardware circuitry and software or to any particular source for the instructions executed by the data processing system.

All or a portion of the described embodiments can be implemented with logic circuitry, such as the above-described ASIC, DSP or FPGA circuitry, including a dedicated logic circuit, controller or microcontroller, or another form of processing core that executes program code instructions. Thus processes taught by the discussion above could be performed with program code such as machine-executable instructions that cause a machine that executes these instructions to perform certain functions. In this context, a “machine” is typically a machine that converts intermediate form (or “abstract”) instructions into processor specific instructions (e.g. an abstract execution environment such as a “virtual machine” (e.g. a Java Virtual Machine), an interpreter, a Common Language Runtime, a high-level language virtual machine, etc.), and/or, electronic circuitry disposed on a semiconductor chip (e.g. “logic circuitry” implemented with transistors) designed to execute instructions such as a general-purpose processor and/or a special-purpose processor. Processes taught by the discussion above may also be performed by (in the alternative to a machine or in combination with a machine) electronic circuitry designed to perform the processes (or a portion thereof) without the execution of program code.

An article of manufacture can be used to store program code. An article of manufacture that stores program code can be embodied as, but is not limited to, one or more memories (e.g. one or more flash memories, random access memories (static, dynamic or other)), optical disks, CD-ROMs, DVD ROMs, EPROMs, EEPROMs, magnetic or optical cards or other type of machine-readable media suitable for storing electronic instructions. Program code may also be downloaded from a remote computer (e.g. a server) to a requesting computer (e.g. a client) by way of data signals embodied in a propagation medium (e.g. via a communication link (e.g. a network connection)).

The term “memory” as used herein is intended to encompass all volatile storage media, such as dynamic random access memory (DRAM) and static RAM (SRAM) or other types of memory described elsewhere in this application.

Computer-executable instructions can be stored on non-volatile storage devices, such as a magnetic hard disk, an optical disk, and are typically written, by a direct memory access process, into memory during execution of software by a processor. One of skill in the art will immediately recognize that the term “machine-readable storage medium” includes any type of volatile or non-volatile storage device that is accessible by a processor.

The preceding detailed descriptions are presented in terms of algorithms and symbolic representations of operations on data bits within a computer memory. These algorithmic descriptions and representations are the tools used by those skilled in the data processing arts to most effectively convey the substance of their work to others skilled in the art. An algorithm is here, and generally, conceived to be a self-consistent sequence of operations leading to the desired result. The operations are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be kept in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The described embodiments also relate to an apparatus for performing the operations described herein. This apparatus can be specially constructed for the required purpose, or it may comprise a general-purpose computer selectively activated or reconfigured by a computer program stored in the computer. Either way, the apparatus provides the means for carrying out the operations described herein. The computer program can be stored in a computer-readable storage medium, such as, but is not limited to, any type of disk including floppy disks, optical disks, CD-ROMs, and magnetic-optical disks, read-only memories (ROMs), RAMs, EPROMs, EEPROMs, magnetic or optical cards, or any type of media suitable for storing electronic instructions, and each coupled to a computer system bus.

The processes and displays presented herein are not inherently related to any particular computer or other apparatus. Various general-purpose systems can be used with programs in accordance with the teachings herein, or it may prove convenient to construct a more specialized apparatus to perform the operations described. The required structure for a variety of these systems will be evident from the description provided in this application. In addition, the embodiments are not described with reference to any particular programming language. It will be appreciated that a variety of programming languages could be used to implement the teachings of the embodiments as described herein.

Numerous specific details have been set forth to provide a thorough explanation of embodiments of the methods, media, and systems for providing data integrity for non-volatile storage. It will be apparent, however, to one skilled in the art, that an embodiment can be practiced without one or more of these specific details. In other instances, well-known components, structures, and techniques have not been shown in detail so as to not obscure the understanding of this description.

Reference in the foregoing specification to “one embodiment” or “an embodiment” means that a particular feature, structure, or characteristic described in connection with the embodiment can be included in at least one embodiment. The appearances of the phrase “in one embodiment” in various places in the specification do not necessarily all refer to the same embodiment.

In the foregoing description, examples may have included subject matter such as a method, a process, a means for performing acts of the method or process, an apparatus, a memory device and/or storage device, and a system for providing data integrity for non-volatile storage, and at least one machine-readable tangible storage medium including instructions that, when performed by a machine or processor, cause the machine or processor to performs acts of the method or process according to embodiments and examples described herein.

Additional example implementations are as follows:

Example 1 is any of a method, system, apparatus or computer-readable medium for a storage server that includes an interface to a storage fabric, a non-volatile storage media to store data received from a remote host over the interface to the storage fabric, a memory to map a stored data to one or more storage locations in the non-volatile storage media, and a processor to control access to a storage location, the processor further to manage an integrity of the stored data mapped to the storage location.

Example 2 is any of the method, system, apparatus or computer-readable medium of Example 1 in which the storage server further includes a peer processor to control access to a second storage location in the non-volatile storage media, and the processor is further to notify the peer processor to perform a data integrity check on a redundant version of the stored data mapped to the second storage location.

Example 3 is any of the method, system, apparatus or computer-readable medium of Examples 1 and 2, where to notify the peer processor, the processor is to transmit to the peer processor any of a unicast notification and a multicast notification to perform the data integrity check on the redundant version of the stored data.

Example 4 is any of the method, system, apparatus or computer-readable medium of Examples 1, 2 and 3 where, to manage the integrity of the stored data mapped to the storage location, the processor is further to receive from the peer processor a communication of the data integrity check on the redundant version of the stored data, determine whether the data integrity check indicates that the redundant version of the stored data is a corrupt version of the stored data, and transmit to the peer processor a correct version of the stored data, the peer processor to repair the corrupt version with the correct version of the stored data.

Example 5 is any of the method, system, apparatus or computer-readable medium of Examples 1, 2, 3 and 4 where, to manage the integrity of the stored data, the processor is further to calculate a checksum on the stored data, receive from the peer processor a second checksum calculated on the redundant version of the stored data, perform a compare and vote algorithm on any one or more of the checksum and the second checksum, and transmit to the remote host a result of the compare and vote algorithm.

Example 6 is any of the method, system, apparatus or computer-readable medium of Examples 1, 2, 3, 4 and 5 where the result of the compare and vote algorithm indicates that the stored data is corrupt data, and the processor is further to receive from the remote host a correct version of the stored data to repair the corrupt data.

Example 7 is any of the method, system, apparatus or computer-readable medium of Examples 1, 2, 3, 4, 5 and 6 where the stored data is an object of a distributed storage system operable on the remote host, the object including any of a redundant version of the object and an erasure coded object.

Example 8 is any of the method, system, apparatus or computer-readable medium of Examples 1, 2, 3, 4, 5, 6 and 7 where the interface, the non-volatile storage media, the memory, the processor and the peer processor are disaggregated resources housed in one or more racks configured for distributed storage of data for the remote host.

Example 9 is any of the method, system, apparatus or computer-readable medium of Examples 1, 2, 3, 4, 5, 6, 7 and 8 where the non-volatile storage media includes any one or more non-volatile storage devices accessible to any one or more of the processor and peer processor using a non-volatile memory express (NVMe) interface.

Example 10 is any of the method, system, apparatus or computer-readable medium of Examples 1, 2, 3, 4, 5, 6, 7, 8 and 9 where the interface to the storage fabric is configured with an NVM over fabric (NVMe-oF) communication protocol and the non-volatile storage devices comprising the non-volatile storage media are accessible through the NVMe-oF communication protocol.

Example 11 is any of the method, system, apparatus or computer-readable medium of Examples 1, 2, 3, 4, 5, 6, 7, 8, 9 and 10 where the processor and peer processor are NVMe-oF storage targets configured with the NVMe-oF communication protocol, the NVMe-oF storage targets corresponding to an NVMe-oF storage initiator configured on the remote host.

Example 12 is any of a system, apparatus or computer-readable medium for a computer-implemented method that includes receiving data from a remote host to store in non-volatile storage of a storage fabric, providing a storage subsystem with access to a storage location in the non-volatile storage, mapping a stored data to the storage location and managing an integrity of data stored in the non-volatile storage, including retrieving the stored data in the storage subsystem with access to the storage location and performing a data integrity check on the stored data.

Example 13 is any of the system, apparatus or computer-readable medium of Example 12 in which the computer-implemented method further includes providing a peer of the storage subsystem with access to a second storage location in the non-volatile storage, notifying the peer to perform a second data integrity check on a redundant version of the stored data mapped to the second storage location, including transmitting to the peer any of a unicast notification and a multicast notification to perform the second data integrity check, receiving from the peer a result of the second data integrity check, determining from the result that the redundant version of the stored data mapped to the second storage location is a corrupt version of the stored data, and transmitting to the peer a correct version of the stored data, the peer to repair the corrupt version, including mapping the correct version of the stored data to a third storage location.

Example 14 is any of the system, apparatus or computer-readable medium of Examples 12 and 13 where the stored data is an object of a distributed storage system operable on the remote host, the object including any of a redundant version of the object and an erasure coded object.

Example 15 is any of the system, apparatus or computer-readable medium of Examples 12, 13 and 14 where access to any of the storage location and the second storage location in the non-volatile storage is performed according to a non-volatile memory express (NVMe) interface and the storage subsystem and the peer of the storage subsystem are storage targets configured with a non-volatile memory express over fabric (NVMe-oF) protocol, the storage targets corresponding to a storage initiator on the remote host configured with the NVMe-oF protocol.

Example 16 is any of a method, system or computer-readable medium for a storage apparatus that includes a network interface controller, non-volatile storage for distributed storage of data received from a remote host through a storage fabric interface on the network interface controller, and circuitry to manage an integrity of a stored data mapped to multiple storage locations in the non-volatile storage, including to generate a first indicator of the integrity of the stored data mapped to a first location of the multiple storage locations, receive a second indicator of an integrity of a redundant version of the stored data mapped to a second location of the multiple storage locations, and determine any of a corrupted data and an uncorrupted data mapped to any of the first and second locations based on the first and second indicators.

Example 17 is any of the method, system or computer-readable medium of Example 16 where to manage the integrity of the stored data the circuitry is further to provide a storage target with access to the first location, provide a peer storage target with access to the second location and where the peer storage target and the storage target are logically connected to a storage initiator on the remote host through the storage fabric interface on the network interface controller.

Example 18 is any of the method, system or computer-readable medium of Examples 16 and 17 where to manage the integrity of the stored data the circuitry is further to transmit, from the storage target to the peer storage target over a target-target interface on the network interface controller, a notification to manage the integrity of the redundant version of the stored data, including any of a unicast notification and a multicast notification to generate the second indicator and a correct version of the stored data, the peer storage target to repair the corrupted data mapped to the second location with the correct version of the stored data.

Example 19 is any of the method, system or computer-readable medium of Examples 16, 17 and 18 where the first and second indicators include checksums calculated on the respective stored data and the redundant version of the stored data and, to manage the integrity of the stored data, the circuitry is further to perform a compare and vote algorithm on the checksums and transmit to the remote host, through the storage fabric interface on the network interface controller, a report of the integrity of the stored data mapped to multiple locations in the non-volatile storage.

Example 20 is any of the method, system or computer-readable medium of Examples 16, 17, 18 and 19 where the circuitry is implemented one or more compute modules of a storage rack, the storage fabric interface is configured with an NVM over fabric (NVMe-oF) communication protocol and the non-volatile storage includes any one or more disaggregated block-addressable non-volatile storage devices accessible to any one or more of the storage target and peer storage target using a non-volatile memory express (NVMe) interface and the NVMe-oF communication protocol.

In the foregoing specification, embodiments have been described with reference to specific exemplary embodiments. It will be evident that various modifications could be made to the described embodiments without departing from the broader spirit and scope of the embodiments as set forth in the following claims. The specification and drawings are, accordingly, to be regarded in an illustrative sense rather than a restrictive sense.

What is claimed is:

1. A storage server, comprising:
an interface to a storage fabric;
a non-volatile storage media to store data received from a remote host over the interface to the storage fabric;
a memory to map a stored data to one or more storage locations in the non-volatile storage media; and
a processor to control access to a storage location, the processor further to manage an integrity of the stored data mapped to the storage location.

2. The storage server of claim 1, further comprising:
a peer processor to control access to a second storage location in the non-volatile storage media; and
wherein the processor is further to notify the peer processor to perform a data integrity check on a redundant version of the stored data mapped to the second storage location.

3. The storage server of claim 2, wherein to notify the peer processor, the processor is to transmit to the peer processor any of a unicast notification and a multicast notification to perform the data integrity check on the redundant version of the stored data.

4. The storage server of claim 2, wherein to manage the integrity of the stored data mapped to the storage location the processor is further to:
receive from the peer processor a communication of the data integrity check on the redundant version of the stored data;
determine whether the data integrity check indicates that the redundant version of the stored data is a corrupt version of the stored data; and
transmit to the peer processor a correct version of the stored data, the peer processor to repair the corrupt version with the correct version of the stored data.

5. The storage server of claim 2, wherein to manage the integrity of the stored data the processor is further to:
calculate a checksum on the stored data;
receive from the peer processor a second checksum calculated on the redundant version of the stored data;
perform a compare and vote algorithm on any one or more of the checksum and the second checksum; and
transmit to the remote host a result of the compare and vote algorithm.

6. The storage server of claim 5, wherein the result of the compare and vote algorithm indicates that the stored data is corrupt data, the processor further to receive from the remote host a correct version of the stored data to repair the corrupt data.

7. The storage server of claim 2, wherein the stored data is an object of a distributed storage system operable on the remote host, the object including any of a redundant version of the object and an erasure coded object.

8. The storage server of claim 2, wherein the interface, the non-volatile storage media, the memory, the processor and the peer processor are disaggregated resources housed in one or more racks configured for distributed storage of data for the remote host.

9. The storage server of claim 2, wherein the non-volatile storage media includes any one or more non-volatile storage devices accessible to any one or more of the processor and peer processor using a non-volatile memory express (NVMe) interface.

10. The storage server of claim 9, wherein:
the interface to the storage fabric is configured with an NVM over fabric (NVMe-oF) communication protocol; and
the non-volatile storage devices comprising the non-volatile storage media are accessible through the NVMe-oF communication protocol.

11. The storage server of claim 10, wherein the processor and peer processor are NVMe-oF storage targets configured with the NVMe-oF communication protocol, the NVMe-oF storage targets corresponding to an NVMe-oF storage initiator configured on the remote host.

12. A computer-implemented method comprising:
receiving data from a remote host to store in non-volatile storage of a storage fabric;
providing a storage subsystem with access to a storage location in the non-volatile storage;
mapping a stored data to the storage location; and
managing an integrity of data stored in the non-volatile storage, including:
retrieving the stored data in the storage subsystem with access to the storage location, and
performing a data integrity check on the stored data.

13. The computer-implemented method of claim 12, further comprising:
providing a peer of the storage subsystem with access to a second storage location in the non-volatile storage;
notifying the peer to perform a second data integrity check on a redundant version of the stored data mapped to the second storage location, including transmitting to the peer any of a unicast notification and a multicast notification to perform the second data integrity check;
receiving from the peer a result of the second data integrity check;
determining from the result that the redundant version of the stored data mapped to the second storage location is a corrupt version of the stored data; and
transmitting to the peer a correct version of the stored data, the peer to repair the corrupt version, including mapping the correct version of the stored data to a third storage location.

14. The computer-implemented method of claim 13, wherein the stored data is an object of a distributed storage system operable on the remote host, the object including any of a redundant version of the object and an erasure coded object.

15. The computer-implemented method of claim 13 wherein:
access to any of the storage location and the second storage location in the non-volatile storage is performed according to a non-volatile memory express (NVMe) interface; and
the storage subsystem and the peer of the storage subsystem are storage targets configured with a non-volatile memory express over fabric (NVMe-oF) protocol, the storage targets corresponding to a storage initiator on the remote host configured with the NVMe-oF protocol.

16. A storage apparatus, comprising:
a network interface controller;
non-volatile storage for distributed storage of data received from a remote host through a storage fabric interface on the network interface controller; and
circuitry to manage an integrity of a stored data mapped to multiple storage locations in the non-volatile storage, including to:
generate a first indicator of the integrity of the stored data mapped to a first location of the multiple storage locations,
receive a second indicator of an integrity of a redundant version of the stored data mapped to a second location of the multiple storage locations, and
determine any of a corrupted data and an uncorrupted data mapped to any of the first and second locations based on the first and second indicators.

17. The storage apparatus of claim 16, wherein to manage the integrity of the stored data the circuitry is further to:
provide a storage target with access to the first location;
provide a peer storage target with access to the second location; and
wherein the peer storage target and the storage target are logically connected to a storage initiator on the remote host through the storage fabric interface on the network interface controller.

18. The storage apparatus of claim 17, wherein to manage the integrity of the stored data the circuitry is further to transmit from the storage target to the peer storage target over a target-target interface on the network interface controller:
a notification to manage the integrity of the redundant version of the stored data, including any of a unicast notification and a multicast notification to generate the second indicator; and
a correct version of the stored data, the peer storage target to repair the corrupted data mapped to the second location with the correct version of the stored data.

19. The storage apparatus of claim 17, wherein the first and second indicators include checksums calculated on the respective stored data and the redundant version of the stored data and, to manage the integrity of the stored data, the circuitry is further to:
perform a compare and vote algorithm on the checksums; and
transmit to the remote host, through the storage fabric interface on the network interface controller, a report of the integrity of the stored data mapped to multiple locations in the non-volatile storage.

20. The storage apparatus of claim 17, wherein:
the circuitry is implemented one or more compute modules of a storage rack;
the storage fabric interface is configured with an NVM over fabric (NVMe-oF) communication protocol; and
the non-volatile storage includes any one or more disaggregated block-addressable non-volatile storage devices accessible to any one or more of the storage target and peer storage target using a non-volatile memory express (NVMe) interface and the NVMe-oF communication protocol.
